(19) United States
(12) Patent Application Publication
(10) Pub. No.: US 2008/0166878 A1
(43) Pub. Date: Jul. 10, 2008

(54) Silicon nanostructures and fabrication thereof

(75) Inventors: Tingkai Li, Vancouver, WA (US); Bruce D. Ulrich, Beaverton, OR (US); Jer-Shen Maa, Vancouver, WA (US); Sheng Teng Hsu, Camas, WA (US)

Correspondence Address: David C. Ripma;Sharp Laboratories of America, Inc., 5750 NW Pacific Rim Boulevard, Camas, WA, 97202, US

(73) Assignee: Sharp Laboratories of America, Inc.

(21) Appl. No.: 11/651,242

(22) Filed: Jan. 8, 2007

(51) Int. Cl. H01L 21/306

(52) U.S. Cl. 438/704; 257/E21.215

(57) ABSTRACT

A method of fabricating silicon nanostructures includes preparing a silicon wafer as a substrate; forming an oxide layer hardmask directly on the silicon substrate; patterning and etching the oxide hardmask; wet etching the silicon wafer to remove oxide to reduce the size of the oxide hardmask and to form nanostructure elements; and dry etching, in one or more steps, the silicon wafer using the oxide hardmask to form a desired nanostructure having substantially parallel vertical sidewalls thereon.

### FIELD OF THE INVENTION

This invention relates to fabrication of nanostructures on silicon substrates to facilitate growth of continuous, low-defect GaN and SiC films formed on silicon substrates for use in power devices, and specifically to a method of fabrication of nanostructures having substantially parallel vertical surfaces.

### BACKGROUND OF THE INVENTION

Small whiskers, also called nanorods, or nanowires, and nanotubes, are of increasing interest due to their physical properties as well as their potential for new nanodevices, such as nanowire field effect transistors, nanosilicon photonics, nano-Si substrates for III-V and SiC devices for LED, high power, and MEMs etc., device applications. Comprehensive studies on the vapor-liquid-solid (VLS) growth of whiskers of silicon, and other materials, with sizes in the 100 nm range began in the 1960's and 1970's. However, fabrication of such devices having well defined radius, position, length, and technological applications, was elusive at that time. Several growth concepts have been developed for semiconductors, ceramics, and metals, allowing the fabrication of whiskers with diameters of 100 nm and length of several micrometers.

Silicon whiskers are normally grown by chemical vapor deposition (CVD), gas-source molecular-beam epitaxy (GS-MBE), and by more recently developed electrochemical wet etching processes, however, CVD and GS-MBE are expensive processes, and are not easily able to provide precise control of nanowire position, distribution and orientation, and present difficulties in removal of any catalysts used to promote nanowire growth. Further, electrochemical wet etching processes require very low resistivity in the silicon substrates, e.g., <0.01 Ωcm, which limits process applications.

Kleimann et al., Toward the formation of three-dimensional nanostructures by electrochemical etching of silicon, Appl. Phys. Lett. 86, 183108-1-183108-3 (2005) describe lithographic etching techniques.

Schubert et al., Silicon nanowhiskers grown on (111)Si substrates by molecular-beam epitaxy, Appl. Phys. Left. Vol. 84, No. 24, pp 4968-4970 (2004) describe use of gold seeds to grow silicon nanowhiskers.

### SUMMARY OF THE INVENTION

A method of fabricating silicon nanostructures includes preparing a silicon wafer as a substrate; forming an oxide layer hardmask directly on the silicon substrate; patterning and etching the, oxide hardmask; wet etching the silicon wafer to remove oxide to reduce the size of the oxide hardmask and to form nanostructure elements; and dry etching, in one or more steps, the silicon wafer using the oxide hardmask to form a desired nanostructure having substantially parallel vertical sidewalls thereon.

It is an object of the invention to provide a method of precisely fabricating nanostructures on a silicon wafer.

It is another object of the invention to provide a method of precisely fabricating nanostructures having substantially parallel vertical surfaces.

This summary and objectives of the invention are provided to enable quick comprehension of the nature of the invention. A more thorough understanding of the invention may be obtained by reference to the following detailed description of the preferred embodiment of the invention in connection with the drawings.

### BRIEF DESCRIPTION OF THE DRAWINGS

FIG. 1 is a block diagram of the method of the invention.

FIG. 2 depicts silicon micro-rods made by oxide hardmask and dry etching processes.

FIG. 3 depicts silicon micro-rods made by use of a photoresist mask and dry etching processes.

FIG. 4 depicts silicon micro-rods made by use of a photoresist mask and two dry etching processes.

FIG. 5 depicts silicon microtips made by use of a photoresist mask and dry etching processes.

FIG. 6 depicts silicon microtips made by use of a photoresist mask and two dry etching processes.

FIG. 7 depicts silicon micro-rods made by use of an oxide hardmask and a two-step dry etching processes.

FIG. 8 depicts silicon micro-rods made by continuous oxidation and wet etching processes.

FIG. 9 depicts silicon microwires made by controlling oxide hardmask and dry etching processes.

FIG. 10 depicts silicon micro-rods made by an oxide hardmask and a two-step dry etching processes.

FIG. 11 depicts silicon microwires made by use of an oxide hardmask, a three-step dry etching and HF wet etching processes.

### DETAILED DESCRIPTION OF THE PREFERRED EMBODIMENTS

A low-cost technique to form various kinds of three-dimensional (3D) structures in silicon from nanosized to submicrometer scale, e.g., 50 nm-1000 nm, is disclosed. There is no physical limitation in application of the method of the invention below 50 nm, as in the above-cited, known prior art. An etching process, which combines conventional dry and conventional wet etching, using a hardmask, such as SiO₂, or other oxide materials, such as ZrO₂, HfO₂, Al₂O₃, TiO₂, Ta₂O₅, Nb₂O₅, Y₂O₃, La₂O₃, etc., to fabricate precise size-controlled silicon nanostructures, including nanorods, nanowires, nanotips and nanotubes is described to exemplify the method of the invention. Using these processes, it is easy to control nanostructure position, distribution and orientation by lithography and substrate orientation. The processes have no special resistivity requirement for the silicon wafers, and also fit within conventional semiconductor processes.

The method of the invention includes provision of an oxide hardmask and two, or more, dry etching steps, combined with a wet etching process, for making silicon nanostructure substrates. Silicon nanostructures having diameters ranging from nanosize to submicrometer scale, e.g., 50 nm to 1000 nm in diameter and 1 μm to 3+μm in height are obtained.

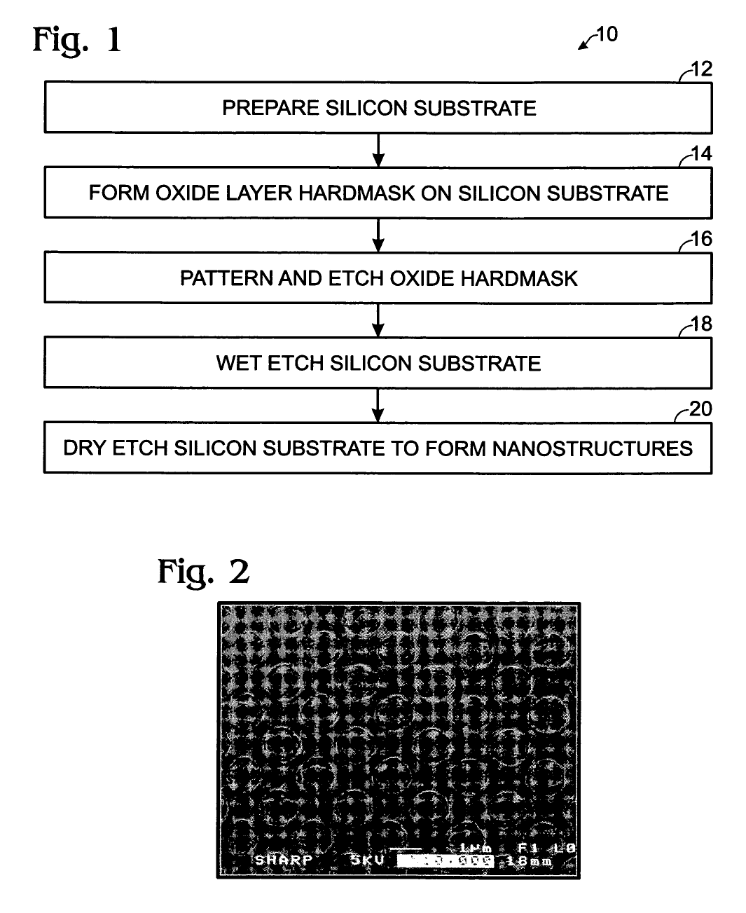

Referring now to FIG. 1, the method of the invention is depicted generally at 10, and includes providing a silicon substrate or wafer 12, which may be silicon (111), silicon (100), or other wafers having other orientations. An oxide layer, e.g., a layer of SiO₂ having a thickness of between about 50 nm to 500 nm, or a layer of a metal oxide having a thickness of between about 10 n to 100 nm, such as Si₃N₄, ZrO₂, HfO₂, Al₂O₃, TiO₂, Ta₂O₅, Nb₂O₅, Y₂O₃, La₂O₃, etc., is formed 14 directly on the silicon wafer, using a thermal oxidation process, CVD or DC sputtering methods. The oxide thickness is determined by the requirements of nanowire length and/or height. Where thermal oxidation is used to form a SiO₂ layer, the substrate is oxidized at a temperature of between about 750° C. and 1100° C.

The oxide layer is covered with photoresist, pattered and etched, 16. Again, the patterning depends on requirements of the nanowire diameter. The oxide layer is etched, stopping at the level of the silicon substrate. The oxide may be further HF wet etched, following application of photoresist and patterning, to further reduce the hardmask size if there is a limitation of the lithography system. The photoresist is then removed.

If oxide materials other than SiO₂ are used, the wafer is fully oxidized, at a low temperature of between about 400° C. to 500° C., which does not significantly oxidize any exposed silicon surface. Any oxidized silicon may be removed by a quick HF wet etch, which will not affect the fully oxidized other metal oxide. The silicon substrate is wet etched 18 to form initial nanostructure elements.

The silicon substrate is now dry etched 20, using the oxide hardmask and two, or more, dry etching steps to configure the nanostructure elements into the desired nanostructure configuration. Further silicon oxidation and HF wet etching may be required to achieve the desired nanostructure size and height.

The wet etching and dry etching protocols are listed in the following Tables.

TABLE 1
Oxide wet etching

| Materials | Etchant | Ratio |
|---|---|---|
| AlOₓ (x < 1.5) | H₂O/HF | 1:1 |
| HfOₓ (x < 2) | H₂O/HF/H₂O₂ | 20:1:1 |
| | H₂O/HF | 1:1 |
| NbOₓ (x < 2.5) | H₂O/HF/H₂O₂ | 20:1:1 |
| | H₂O/HF | 1:1 |
| SiO₂ | Buffered oxide etching | |
| | H₂O/HF = 50:1 etching rates: 2 Å/second | |
| | H₂O/HF = 20:1 | |
| SiN | Phosphoric acid (85%), 170° C., DI water | |
| | injection of one drop begins at 3° C. below set | |
| | temperature point | |
| TaOₓ (x < 2) | H₂O/HF/H₂O₂ | 20:1:1 |
| | H₂O/HF | 1:1 |
| TiOₓ (x < 2) | H₂O/HF/H₂O₂ | 20:1:1 |
| | H₂O/HF | 1:1 |
| ZrOₓ (x < 2) | H₂O/HF/H₂O₂ | 20:1:1 |
| | H₂O/HF | 1:1 |

TABLE 2
SiO₂ dry etching conditions

| RF Source | RF Bias power | Pressure | | |
|---|---|---|---|---|
| Power (W) | (W) | (mtorr) | C₃F₈ (sccm) | Ar (sccm) |
| 1000–2500 | 200–1000 | 3–6 | 10–30 | 20–40 |

TABLE 3
Dry etching conditions for DC-sputtering of other oxide materials

| RF Top | RF Bottom | Pressure | BCl₃ | | Etching time |
|---|---|---|---|---|---|
| Power (W) | Power (W) | (mtorr) | (sccm) | Cl₂ (sccm) | (sec) |
| 300–450 | 100–150 | 3–10 | 20–40 | 50–70 | 10–50 |

TABLE 4
Etching conditions for silicon nanostructures

| RF Top | RF Bottom | Pressure | | HBr | Etching time |
|---|---|---|---|---|---|
| Power (W) | Power (W) | (mtorr) | Cl₂ (sccm) | (sccm) | (sec) |
| 200–300 | 20–60 | 10–20 | 30–50 | 60–100 | 200–500 |

TABLE 5
Alternate etching conditions for silicon nanostructures

| RF Top | RF Bottom | Pressure | | O-10 | Etching time |
|---|---|---|---|---|---|
| Power (W) | Power (W) | (mtorr) | Cl₂ (sccm) | (sccm) | (sec) |
| 150–200 | 900–1100 | 3–8 | 80–120 | 10–30 | 100–300 |

The etching rate of silicon is much higher than that of SiO₂ and other metal oxides when using the silicon dry etching protocols of Tables 4 and 5, thus, a SiO₂, or other metal oxide layer, may be used as a hardmask for silicon nanostructure etching. Silicon nanostructures having diameters from nanosize to submicrometer, e.g., 50 nm-1000 nm (diameter)×1 μm to 3+μm (height) are obtained. Utilization of thermal oxidation and oxide etching processes can produce thinner silicon nanowires.

### EXAMPLE 1

### Fabrication of Silicon Microrods Using Oxide Hardmask and Dry Etching Step(s)

A silicon wafer, e.g., Si (111) is prepared. A layer of SiO₂, having a thickness of about 500 nm, is formed directly on the silicon wafer, using a thermal oxidation process. The oxide layer is coated with photoresist, patterned with appropriate diameter×distance of between about 0.8 μm×1.6 μm. The oxide is etched to form nanostructure elements using the protocol of Table 6, and the photoresist then removed. Initially, the nanostructure elements have a somewhat pyramidal form.

TABLE 6
Oxide etching conditions

| RF Source | RF Bias power | Pressure | | |
|---|---|---|---|---|
| Power (W) | (W) | (mtorr) | C₃F₈ (sccm) | Ar (sccm) |
| 1800 | 600 | 4 | 18 | 30 |

The silicon is dry etched using the oxide hardmask and the protocol of Table 7.

TABLE 7
Etching conditions

| RF Top | RF Bottom | Pressure | | O-10 | Etching time |
|---|---|---|---|---|---|
| Power (W) | Power (W) | (mtorr) | Cl₂ (sccm) | (sccm) | (sec) |
| 175 | 1000 | 5 | 100 | 20 | 300 |

The wafer is cleaned with HF, 50:1 for 40 minutes, to remove the SiO₂ hardmask. The resultant wafer has the desired nanostructure configuration of silicon microrods thereon, having a 0.8 μm (diameter)×0.5 μm (height)×1.6 μm (distance), and are depicted in the microphotograph of FIG. 2, wherein the microrods, with the substrate horizontally oriented, have substantially parallel, vertical side walls. The parameters for wet and dry etching provide optimal conditions, which result in the substantially straight, parallel sides of the nanostructure configuration. Use of parameters other than the optimal parameters does not provide the desired results, thus, the parameters set forth in the tables are deemed critical parameters.

### EXAMPLE 2

### Silicon Microrods—Made by Photoresist Mask and Two Dry Etching Steps

A silicon wafer is prepared. The wafer is coated with photoresist and patterned to provide a mask which result in a nanostructure having a diameter×distance of 0.8 μm×1.6 μm. The silicon of the wafer is dry etched using the protocol of Table 8.

TABLE 8
First step etching conditions

| RF Top | RF Bottom | Pressure | | HBr | Etching time |
|---|---|---|---|---|---|
| Power (W) | Power (W) | (mtorr) | Cl₂ (sccm) | (sccm) | (sec) |
| 250 | 40 | 15 | 40 | 80 | 500 |

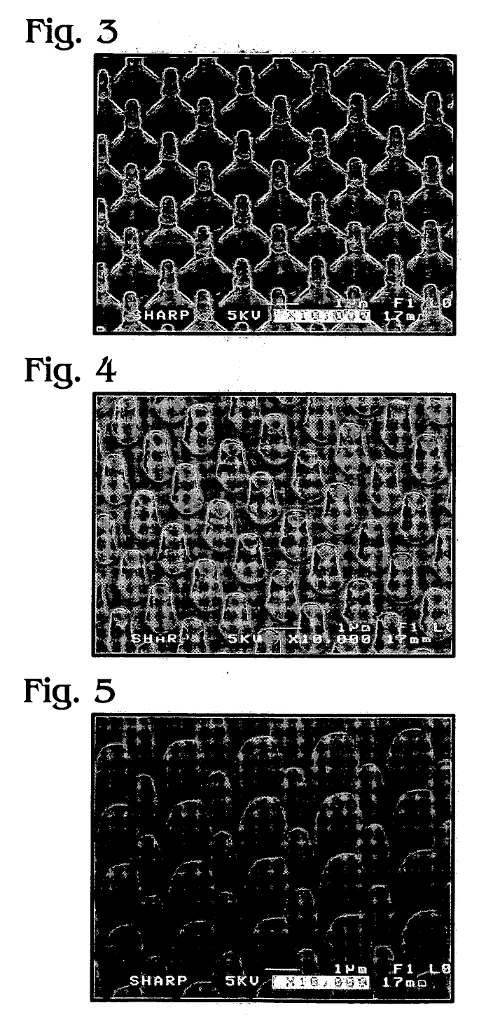

Following the etching, the photoresist is removed, and the wafer cleaned in HF 50:1 for 5 minutes to remove any surface SiO₂. Silicon microrods having a 0.5 μm (diameter)×2 μm (height)×1.6 μm (distance) are formed, as shown in FIG. 3, wherein the microrods extend upward from a conical base. The wafer is again dry etched, using Table 7 protocols. The silicon microrods, made by photoresist mask and two dry etching processes, having a 0.8 μm (diameter)×2 μm (height)×1.6 μm (distance), as shown in FIG. 4, wherein the conical base is removed during the two dry etching processes, leaving a microrod having substantially parallel, vertically oriented sides.

### EXAMPLE 3

### Silicon Microtips—Made by Photoresist Mask and Dry Etching Processes

A silicon (111) wafer is prepared. A layer of SiO₂, having a thickness of about 500 nm is formed on the silicon wafers using a thermal oxidation process. The oxide layer is coated with photoresist, and patterned to produce nanostructures having a diameter×distance ranges of 0.8 μm×1.6 μm and 1.5 μm×2 μm. The oxide layer is etched, stopping at the level of the silicon substrate, using Table 6 protocols. The photoresist is removed. The silicon wafer is dry etched using Table 7 protocols in the first step and Table 8 protocols in the second step.

The wafer is cleaned in HF 50:1 for 40 minutes to remove the SiO₂ hardmask. The resulting wafer has silicon microtips having diameters of between about 0.8 μm to 1.5 μm, a height of about 3 μm, and spacing of about 2 μm, as shown in FIG. 5.

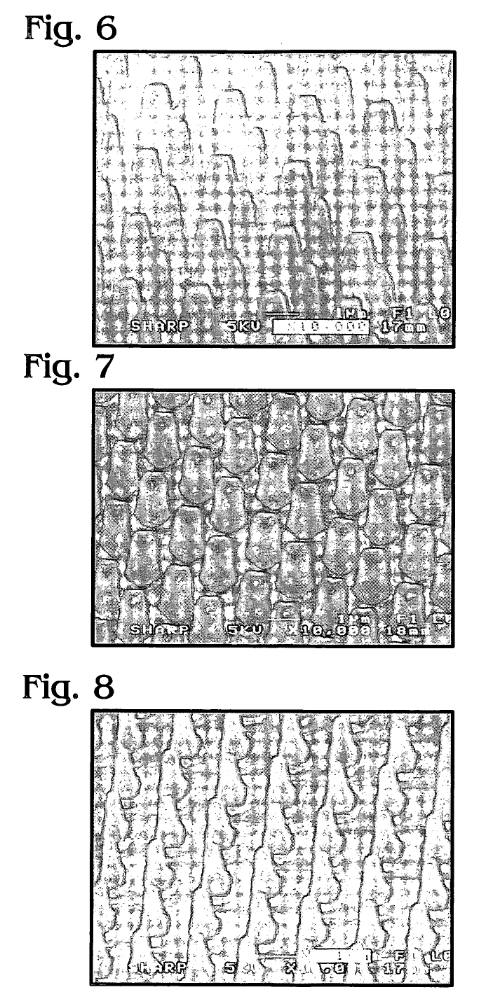

The silicon is further oxidized to an oxide thickness of about 200 nm by thermal oxidation and HF 50:1 wet etching for 40 minutes, resulting in silicon microtips having a range of between about 0.5 μm to 1 μm(diameter)×3 μm (height)×2 μm (distance), as shown in FIG. 6.

### EXAMPLE 4

### Silicon Nanorods Made After Continuous Oxidation and Wet Etching Processes

A silicon (110) wafer is prepared. A layer of SiO₂, having a thickness of about 500 nm is formed on the silicon wafers using a thermal oxidation process. The oxide is coated with photoresist and patterned to provide for nanostructures having a diameter×distance of 0.8 μm×1.6 μm. The patterned oxide is etched using Table 6 protocols, stopping at the level of the silicon wafer. The silicon wafer is dry etched using Table 8 protocols in the first step and Table 7 protocols in the second step. The wafer is cleaned in HF 50:1 for 40 minutes to remove the SiO₂ hardmask. The resultant silicon microtips have a 0.8 μm (diameter)×2 μm (height)×1.6 μm (distance), as shown in FIG. 7. The silicon is further oxidized to a thickness of about 200 nm by thermal oxidation and HF 50:1 wet etching for 20 minutes, resulting in the silicon microtips having a 0.4 μm (diameter)×2 μm (height)×1.6 μm (distance), as shown in FIG. 8.

### EXAMPLE 5

### Silicon Nanowire Made by Controlling Oxide Hardmask and Dry Etching Processes

A silicon (100) wafer is prepared. A layer of SiO₂ is formed directly on the silicon wafer to a thickness of about 500 nm using a thermal oxidation process. The oxide layer is coated with photoresist, and patterned to produce a resultant nanostructure having a diameter×distance of 0.8 μm×1.6 μm. The oxide is etched, using Table 6 protocols, stopping at the level of the silicon substrate. The wafer is cleaned in HF 50:1 wet etching oxide for 20 minutes. The photoresist is removed. The wafer is then dry etched, using Table 8 protocols.

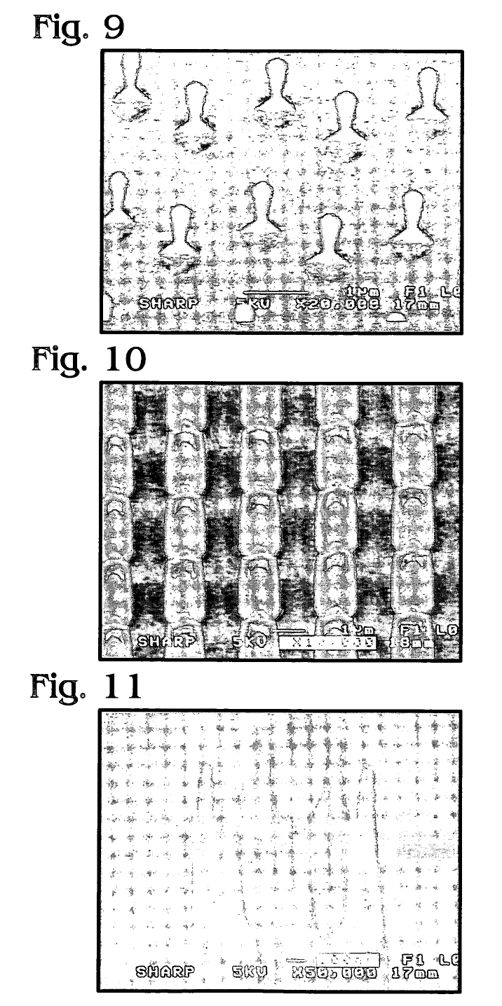

The wafer is again cleaned in HF 50:1 for 40 minutes to remove the SiO₂ hardmask, resulting in silicon microwires having a mixture of diameters of between about 0.2 μm to 0.3 μm×1 μm (height)×1.6 μm (distance), as shown in FIG. 9.

### EXAMPLE 6

### Silicon Nanowires Made by Oxide Hardmask; Three Step Dry Etching and HF Wet Etching Processes

A silicon (111) wafer is prepared. A layer of SiO₂ having a thickness of about 500 nm is formed directly on the silicon wafer using a thermal oxidation process. The oxide is coated with photoresist and patterned to provide a nanostructure having a diameter×distance of 0.8 μm×1.6 μm. The oxide is etched, using Table 6 protocols, stopping at the level of the silicon wafer. The photoresist is removed. The silicon is dry etched using Table 8 protocols in the first step and Table 7 protocols in the second step. The resultant silicon microrods have a size of 0.8 μm (diameter)×3 μm (height)×1.6 μm (distance), as shown in FIG. 10.

Etching of the silicon continues using Table 8 protocols. The wafer is cleaned in HF 50:1 for 80 minutes to remove the SiO₂ hardmask, producing silicon microwire having a 50 nm to 100 nm (diameter)×3 μm (height)×1.6 μm (distance), as shown in FIG. 11.

Thus, a low-cost technique to form various kinds of three-dimensional (3D) structures in silicon from nanosized to submicrometer scale (50 nm to 1000 nm) has been disclosed. It will be appreciated that further variations and modifications thereof may be made within the scope of the invention as defined in the appended claims.

We claim:

1. A method of fabricating silicon nanostructures, comprising:
preparing a silicon wafer as a substrate;
forming an oxide layer hardmask directly on the silicon substrate;
patterning and etching the oxide hardmask;
wet etching the silicon wafer to remove oxide to reduce the size of the oxide hardmask and to form nanostructure elements; and
dry etching, in one or more steps, the silicon wafer using the oxide hardmask to form a desired nanostructure having substantially parallel vertical sidewalls thereon.

2. The method of claim 1 which includes, after said dry etching, oxidizing the silicon wafer and HF wet etching to produce nanostructure elements of a desired size.

3. The method of claim 1 wherein etching parameters for silicon nanostructure elements are:

| RF Top | RF Bottom | Pressure | | HBr | Etching time |
|---|---|---|---|---|---|
| Power (W) | Power (W) | (mtorr) | Cl₂ (sccm) | (sccm) | (sec) |
| 200–300 | 20–60 | 10–20 | 30–50 | 60–100 | 200–500 |

4. The method of claim 1 wherein etching parameters for silicon nanostructure elements are:

| RF Top | RF Bottom | Pressure | | O-10 | Etching time |
|---|---|---|---|---|---|
| Power (W) | Power (W) | (mtorr) | Cl₂ (sccm) | (sccm) | (sec) |
| 150–200 | 900–1100 | 3–8 | 80–120 | 10–30 | 100–300 |

5. The method of claim 1 wherein the dry etching parameters are taken from the group of etching parameters consisting of:

| RF Top | RF Bottom | Pressure | | O-10 | Etching time |
|---|---|---|---|---|---|
| Power (W) | Power (W) | (mtorr) | Cl₂ (sccm) | (sccm) | (sec) |
| 175 | 1000 | 5 | 100 | 20 | 300 |

and

| RF Top | RF Bottom | Pressure | | HBr | Etching time |
|---|---|---|---|---|---|
| Power (W) | Power (W) | (mtorr) | Cl₂ (sccm) | (sccm) | (sec) |
| 250 | 40 | 15 | 40 | 80 | 500 |

6. The method of claim 1 wherein said forming an oxide hardmask includes forming a SiO₂ oxide mask by thermal oxidation at a temperature of between about 750° C. to 1100° C.

7. A method of fabricating silicon nanostructures, comprising:
preparing a silicon wafer as a substrate;
forming an oxide layer hardmask directly on the silicon substrate by thermal oxidation, wherein the oxide material is taken from the group of oxides consisting of SiO₂, ZrO₂, HfO₂, Al₂O₃, TiO₂, Ta₂O₅, Nb₂O₅, Y₂O₃, and La₂O₃;
patterning and etching the oxide hardmask;
wet etching the silicon wafer to remove oxide to reduce the size of the oxide hardmask and to form nanostructure elements; and
dry etching, in one or more steps, the silicon wafer using the oxide hardmask to form a desired nanostructure having substantially parallel vertical sidewalls thereon.

8. The method of claim 7 which includes, after said dry etching, oxidizing the silicon wafer and HF wet etching to produce nanostructure elements of a desired size.

9. The method of claim 7 wherein etching parameters for silicon nanostructure elements are:

| RF Top | RF Bottom | Pressure | | HBr | Etching time |
|---|---|---|---|---|---|
| Power (W) | Power (W) | (mtorr) | Cl₂ (sccm) | (sccm) | (sec) |
| 200–300 | 20–60 | 10–20 | 30–50 | 60–100 | 200–500 |

10. The method of claim 7 wherein etching parameters for silicon nanostructure elements are:

| RF Top | RF Bottom | Pressure | | O-10 | Etching time |
|---|---|---|---|---|---|
| Power (W) | Power (W) | (mtorr) | Cl₂ (sccm) | (sccm) | (sec) |
| 150–200 | 900–1100 | 3–8 | 80–120 | 10–30 | 100–300 |

11. The method of claim 7 wherein the dry etching parameters are taken from the group of etching parameters consisting of:

| | | | | | Etching |
|---|---|---|---|---|---|
| RF Top | RF Bottom | Pressure | | | time |
| Power (W) | Power (W) | (mtorr) | Cl₂ (sccm) | O-10 (sccm) | (sec) |
| 175 | 1000 | 5 | 100 | 20 | 300 |

and

| | | | | | Etching |
|---|---|---|---|---|---|
| RF Top | RF Bottom | Pressure | | | time |
| Power (W) | Power (W) | (mtorr) | Cl₂ (sccm) | HBr (sccm) | (sec) |
| 250 | 40 | 15 | 40 | 80 | 500 |

12. The method of claim 7 wherein said forming a SiO₂ oxide mask by thermal oxidation includes thermally oxidizing the substrate at a temperature of between about 750° C. to 1100° C.
